(19) United States
(12) Patent Application Publication
(10) Pub. No.: US 2008/0216997 A1
(43) Pub. Date: Sep. 11, 2008

(54) Heat plate construction and attachment for dismounting heat plate

(75) Inventors: Feng-Ku Wang, Taipei (TW); Hua-Fong Chen, Taipei (TW)

Correspondence Address: RABIN & Berdo, PC, 1101 14TH STREET, NW, SUITE 500, WASHINGTON, DC, 20005, US

(73) Assignee: INVENTEC CORPORATION, Taipei (TW)

(21) Appl. No.: 11/715,325

(22) Filed: Mar. 8, 2007

(51) Int. Cl. H05K 7/20

(52) U.S. Cl. 165/185; 361/704

(57) ABSTRACT

A heat plate construction is provided, which is applicable for being fixed on a circuit board and contacting with a chip to perform a heat exchange. The heat plate construction includes a heat plate body and at least one buffer element. The heat plate body has a plurality of fixing points fixed on the circuit board and located outside the contacting region between the heat plate body and the chip. The buffer element is disposed outside the contacting region between the heat plate body and the chip, and the height of the buffer element is equal to a distance between the heat plate body and the circuit board, such that when the heat plate is dismounted, the buffer element relieves a force for the heat plate to press against the chip, so as to protect the chip from being damaged.

### BACKGROUND OF THE INVENTION

1. Field of Invention

The present invention relates to a heat plate construction. More particularly, the present invention relates to a heat plate construction, which is capable of providing a balanced buffer force.

2. Related Art

Electronic elements in computer equipments, such as a central processing unit (CPU) chip and a power integrated circuit (IC), generate heats during the operation, and the working temperature is increased accordingly. Since the working temperature greatly affects whether the computer equipment is crashed or not, in order to reduce the working temperature of the heating electronic element and to maintain the effective operation, various heatsinks are designed through a heatsink design. For example, a heatsink module is pressed on the CPU chip on a circuit board, and locked on the circuit board, such that the heatsink module closely contacts with the CPU chip, and thereby achieving a heat dissipation effect.

Referring to FIGS. 1 and 2, a plurality of corresponding screw holes is generally disposed between a circuit board 10a and a heatsink module 30a, which is provided for the user to use a locking element 50a to closely lock a heatsink module 30a on the circuit board 10a. In consideration of wiring, electrical properties, and mechanical properties, the circuit board 10a has at least three screw holes, wherein a triangular allocation region is defined by the three screw holes, and the CPU chip 20a is located in the allocation region.

However, when the user intends to remove the heatsink module 30a from the circuit board 10a, a locking element 50a is firstly loosened. At this time, the other two locking elements are still in the locking state and still have the internal stress generated during locking, so that a loosened end (as shown in FIG. 2) of the heatsink module 30a may become warped, and thus, the CPU chip 20a close to the locking element 50a that is not loosened may be pressed. Particularly, when the user makes the first locking element 50a be loosened, one end of the heatsink module 30a becomes warped due to being forced by the stress effect of the locking element 50a, but the other two ends of the heatsink module 30a are still forced by the stress effect of the locking element 50a and thereby being fixed on the circuit board 10a. Therefore, the external part of the contacting region between the heatsink module 30a and the CPU chip 20a may press against the CPU chip 20a, which even causes the CPU chip 20a to be pressed and damaged.

For example, in disclosed in U.S. Patent Publication No. 2004/0188079 (hereinafter referred as Case 079), a heatsink module applied to a chip of a notebook computer is provided. Referring to FIG. 2 of Case 079, a plurality of pads made of an elastic material is disposed under a base platform corresponding to a plurality of fixing holes. When the heatsink module is assembled, the plurality of fixing holes is used to fix the base platform on the surface of the chip, and to attach the base platform on the surface of the chip with a contacting surface. Meanwhile, the plurality of pads is made to contact with the periphery of the chip of the notebook computer, so as to provide a balanced buffer force. In Case 079, the pads are disposed outside the contacting region between the base platform and the chip, so as to protect the chip from being pressed and damaged by the base platform during the assembling process. However, since each pad is located at positions on the line between two fixing holes, but not disposed on the region of the base platform between the fixing hole and the chip, when the user dismounts the screw on one end of the base platform to loose the base platform, the loosened end of the base platform is not forced by the stress effect of the locking element and becomes warped, and the other end that the screw is not dismounted is still forced by the stress effect of the screw and thereby being fixed on the circuit board. In this manner, the region of the base platform between the fixing hole and the chip may directly press against the CPU chip, and thus, the CPU chip may be pressed and damaged.

### SUMMARY OF THE INVENTION

In view of the above conventional art, although the base platform has been disposed with pads, the pads are not disposed on the region of the base platform between the fixing hole and the chip, such that the base platform at this part may directly press against the central processing unit (CPU) chip, which cannot fully protect the chip, and thus, it is not the optimal design of the heat plate. Therefore, the present invention is directed to a heatsink module, which is capable of well protecting the chip.

In order to achieve the above object, the present invention provides a heat plate construction, which is fixed on a circuit board and contacts with a heat source to perform a heat exchange. The heat plate construction comprises a heat plate body and at least one buffer element. The heat plate body has a plurality of fixing points located outside the contacting region between the heat plate body and the heat source, thereby being fixed on the circuit board and contacting with the heat source. The buffer element is disposed outside the contacting region between the heat plate and the heat source. The height of the buffer element is substantially equal to a distance between the heat plate body and the circuit board.

The present invention further provides an attachment for dismounting a heat plate.

The heat plate is fixed on a circuit board and contacts with a heat source sandwiched there-between to perform a heat exchanged. The attachment comprises a handle portion for being held by the user, two supporting arms, and a plurality of buffer elements. Each supporting arm extends from the handle portion and penetrates between the fixing position of the heat plate and the heat source. Each buffer element is disposed on the supporting arm, and located between the supporting arm and the circuit board. The height of the buffer element is substantially equal to a distance between the supporting arm and the circuit board.

In the heat plate construction and the attachment for dismounting the heat plate according to the present invention, when the user dismounts a first locking element on the heat plate, the heat plate is loosed and becomes warped, the remaining end is still fixed on the circuit board under the stress effect of the locking element, but the buffer element is disposed between the fixing points of the heat plate and the heat source, so the other parts of the heat plate that are not loosed may press against the buffer element instead of the chip. Therefore, the buffer element can absorb the pressing force of the heat plate, so as to protect the chip from being damaged. In addition, the attachment with the buffer element also can be used to dismount the heat plate, and the force for the heat plate to press against the chip is also absorbed. Besides being convenient for the user to operate, it also reduces the probability for damaging the chip when the heat plate is removed.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus is not limitative of the present invention, and wherein:

FIG. 1 is a schematic back view of a heatsink module assembled on a circuit board in the conventional art;

FIG. 2 is a schematic side view of dismounting the heatsink module in the conventional art;

FIG. 3 is an exploded view of a heat plate construction assembled on a circuit board according to an embodiment of the present invention;

FIG. 4A is an assembled view of the heat plate construction assembled on the circuit board according to an embodiment of the present invention;

FIG. 4B is a schematic side view of dismounting the heatsink module according to an embodiment of the present invention;

FIG. 4C is a schematic back view of a square-shaped heat plate body and a buffer element assembled on the circuit board according to an embodiment of the present invention;

FIG. 5 is a schematic side view of another heat plate construction assembled on the circuit board according to an embodiment of the present invention;

FIG. 6 is a stereogram of an attachment for dismounting the heat plate according to an embodiment of the present invention;

FIG. 7 is a schematic back view of the attachment, for dismounting the heat plate, assembled between the circuit board and the heat plate according to an embodiment of the present invention;

FIG. 8A is a schematic side view of the attachment, for dismounting the heat plate, assembled between the circuit board and the heat plate according to an embodiment of the present invention;

FIG. 8B is a schematic back view of the attachment, for dismounting the heat plate, applied to the square-shaped heat plate according to an embodiment of the present invention, and each supporting arm is located outside the fixing position; and

FIG. 9 is a schematic back view of another attachment, for dismounting the heat plate, assembled between the circuit board and the heat plate according to an embodiment of the present invention.

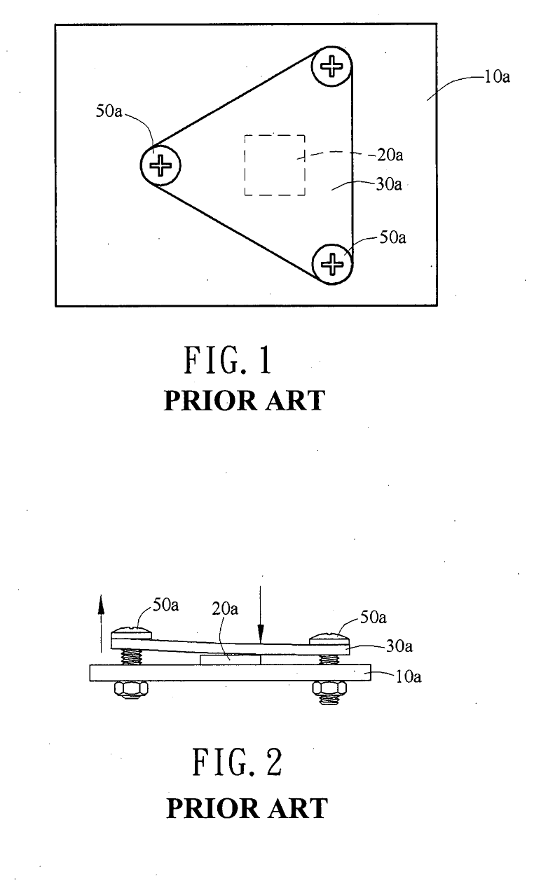

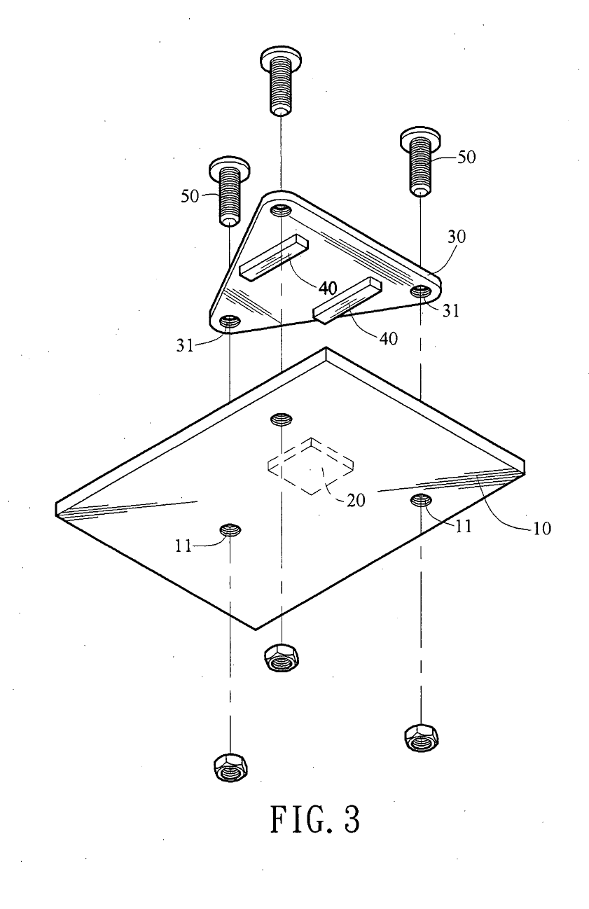

### DETAILED DESCRIPTION OF THE INVENTION

In order to make a further understanding of the objectives, construction, features, and functions of the present invention, the detailed description is given below through the following embodiments.

In the heat plate construction and the attachment for dismounting the heat plate according to the present invention, the heat plate contacts with the heat source. The heat source may be a CPU chip, a north bridge chip, a south bridge chip, and the like, but it is not limited to the CPU chip, the north bridge chip, and the south bridge chip, and for example, the integrated circuits (ICs) chip that generates heats also can be applied to the technique provided by the present invention. In the following detailed description of the present invention, the CPU chip is set as an example for an application embodiment of the present invention.

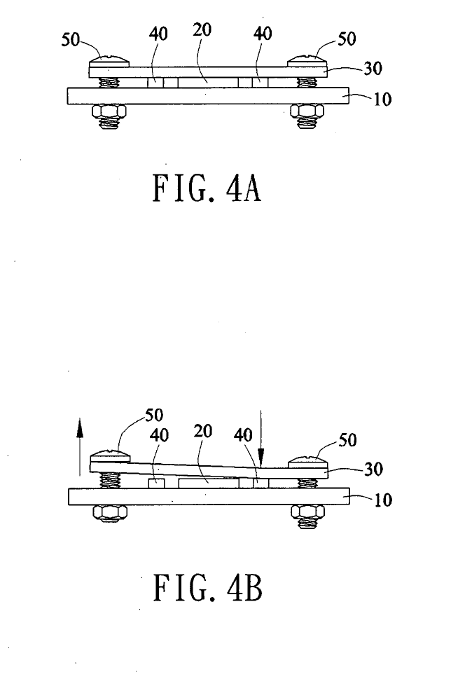

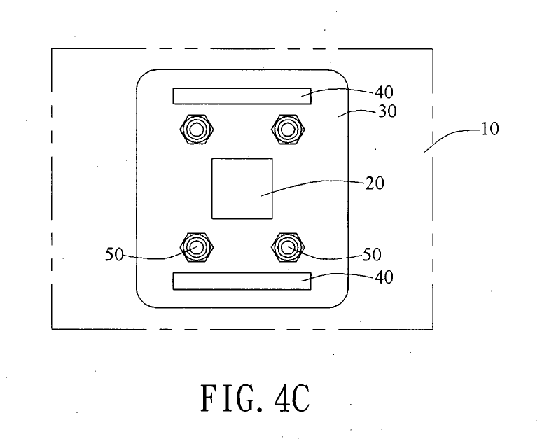

Referring to FIGS. 3, 4A, and 4B, the heat plate construction in this embodiment of the present invention is fixed on the circuit board 10 and contacts with the CPU chip 20 to perform a heat exchange. The heat plate construction includes a heat plate body 30 and at least one buffer element 40. The heat plate body 30 is triangular-shaped herein, which can be another geometric shape, such as a square and a regular polygon shape, but not limited to be triangular-shaped. The heat plate body 30 has a plurality of fixing points, and each fixing point is located at a position outside the contacting region between the heat plate body 30 and the CPU chip 20. Each fixing point is a through-hole 31 passing through the heat plate body 30, for a plurality of locking elements 50 to penetrate there through. The locking elements 50 are, for example, screws, nuts, etc. The circuit board 10 has a plurality of fixing holes 11 at positions corresponding to the through-holes 31 of the heat plate body 30. When one end surface of the heat plate body 30 is attached on the CPU chip 20, each through-hole 31 is corresponding to each fixing hole 11, for the plurality of locking elements 50 to penetrate there through, so as to fix the heat plate body 30 on the circuit board 10.

The buffer element 40 is disposed outside the contacting region between the heat plate body 30 and the CPU chip 20. Herein, the buffer element 40 is located between the contacting region of the heat plate body 30 and the CPU chip 20 and the through-hole 31 of the heat plate body 30. Furthermore, the number of the buffer elements 40 is at least one. Once it is intended to dismount the heat plate body 30 from the circuit board 10, one side where the buffer element 40 is oppositely disposed is dismounted first, so as to achieve a buffering effect. Herein, the number of the buffer elements 40 is two, and thus, when it is intended to dismount the heat plate body 30 from the circuit board 10, any side of the heat plate body 30 is randomly selected to be dismounted first. In addition, the buffer element 40 is a resilient element, and its thickness is substantially equal to a distance between the heat plate body 30 and the circuit board 10, and the buffer element 40 may be used to fill between the heat plate body 30 and the circuit board 10, such that two ends of the buffer element 40 contact with the heat plate body 30 and the circuit board 10 respectively. The buffer element 40 is, for example, a resilient element without electrically conductive property, such as a bakelite and a rubber spring, and thus, when the heat plate body 30 is fixed on the circuit board 10, the buffer element 40 has a force for pushing against the heat plate body 30 under a normal force.

Referring to FIGS. 3, 4A, and 4B, when being assembled, each through-hole 31 is made to be corresponding to each fixing hole 11, and each locking element 50 passes through each through-hole 31 and each fixing hole 11, so as to fix the heat plate body 30 on the circuit board 10. Meanwhile, each buffer element 40 is located between the heat plate body 30 and the circuit board 10, and the heat plate body 30 is attached on the CPU chip 20, such that the heat plate body 30 transmits the heat generated by the CPU chip 20 to the heat transfer element, and then, the heat transfer element transfers the heat to the heat-dissipation region for dissipating the heats. When it is intended to dismount the heat plate body 30 from the circuit board 10, the user uses a tool to dismount a first locking element 50 to loose the heat plate body 30, such that the loosened end of the heat plate body 30 is no longer affected by the stress effect of the locking element 50 and becomes warped, and the other end that the locking element 50 is not dismounted is still fixed on the circuit board 10 under the stress effect of the locking element 50. However, the buffer element 40 is disposed outside the contacting region between the heat plate body 30 and the CPU chip 20, the end of the heat plate body 30 that is not loosed may press against the buffer element 40, and thus, the buffer element 40 may absorb the pressing force of the heat plate body 30 (as shown in FIG. 4B).

Referring to FIG. 4C, the position of the buffer element 40 is not limited to the above description, for example, when the heat plate body 30 is square-shaped, the buffer element 40 may also be located outside the through-hole 31 of the heat plate body 30. When the heat plate body 30 is dismounted according to the above steps, the buffer element -40 may also absorb the pressing force to the heat plate body 30.

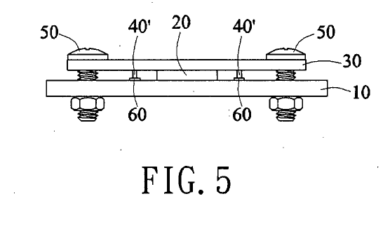

Referring to FIG. 5, it is a schematic side view of another heat plate construction assembled on the circuit board according to an embodiment of the present invention. The structure in this embodiment is approximately the same as that described above, with the difference lying in the structure of the buffer element 40′. The above buffer element 40 is a resilient element without the electrically conductive property. Herein, the buffer element 40′ is a resilient element with the electrically conductive property, for example, the metal spring etc., and an insulating block 60 is disposed between the buffer element 40′ and the circuit board 10, so as to prevent the buffer element 40′ from directly contacting with the circuit board 10 to cause the short circuit of the circuit board 10. Furthermore, the thickness of the insulating block 60 together with the buffer element 40′ is substantially equal to a distance between the heat plate body 30 and the circuit board 10.

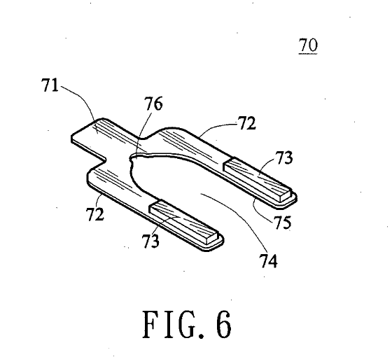

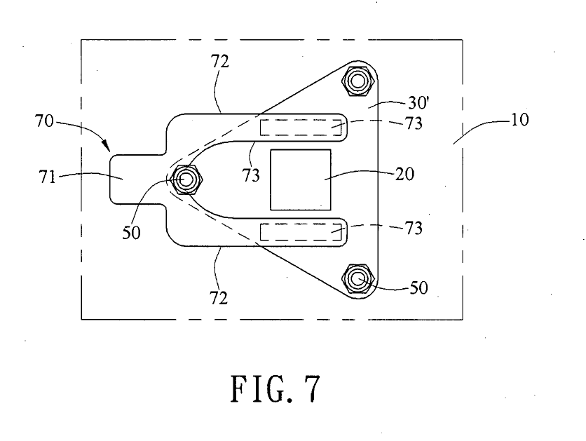

Referring to FIGS. 6, 7, 8A, and 8B, the attachment 70 for dismounting the heat plate of the present invention is applied to dismount the heat plate 30′ from the circuit board 10. The heat plate 30′ is triangular-shaped herein, it may also be another geometric shape, such as a square and a regular polygon shape, and it is not limited to triangular-shaped. A plurality of through-holes passing through the heat plate 30′ is formed on the fixing positions of the heat plate 30′, and each through-hole is located outside the contacting region between the heat plate 30′ and the CPU chip 20, for the plurality of locking elements 50 to penetrate there through, and thus, the heat plate 30′ is fixed on the circuit board 10 and contacts with the CPU chip 20 sandwiched there-between to perform the heat exchange.

The attachment 70 includes a handle portion 71 and two supporting arms 72. The handle portion 71 is provided for the user to hold by hands or hand tools. The two supporting arms 72 are extended from the handle portion 71 and penetrate between the through-hole position of the heat plate 30′ and the CPU chip 20. Furthermore, the handle portion 71 and each supporting arm 72 together form a hollow portion 74, and the hollow portion 74 has an annular wall 75 having a positioning slot 76 matching with the locking element 50 and thereby being engaged with the locking element 50. The supporting arm 72 is made of an elastic plastic material, so as to serve as a buffer.

However, the attachment 70 also includes a plurality of buffer elements 73, and each buffer element 73 is located on each supporting arm 72 and is extended from each supporting arm 72. Herein, for another example, the buffer element 73 and the supporting arm 72 are two separated elements, and the buffer element 73 is disposed at the supporting arm 72 and thereby being integrated as a whole (as shown in FIG. 6), which is taken as an application example herein.

The buffer element 73 is located between each supporting arm 72 and the circuit board 10, and the thickness of each buffer element 73 together with the height of each supporting arm 72 is substantially equal to a distance between the heat plate 30′ and the circuit board 10. In addition, the buffer element 73 is a resilient element, which has a force for pushing against each supporting arm 72 under a normal state, when each supporting arm 72 penetrates between the heat plate 30′ and the circuit board 10. The buffer element 73 may be, for example, resilient elements without the electrically conductive property, such as bakelite and rubber spring, or resilient elements with the electrically conductive property, such as metal springs. An insulating block is further disposed between the buffer element 73 and the circuit board 10, so as to prevent the buffer element 73 from directly contacting with the circuit board to cause the short circuit of the circuit board. Herein, each buffer element 73 is, for example, the bakelite.

Referring to FIGS. 6, 7, 8A, and 8B, when the heat plate 30′ is assembled on the circuit board 10, the locking element 50 is made to pass through each through-hole and the circuit board 10, so as to fix the heat plate 30′ on the circuit board 10. The heat plate 30′ is attached on the CPU chip 20, such that the heat plate 30′ transmits the heat generated by the CPU chip 20 to the heat transfer element, and then, the heat transfer element transfers the heat to the heat dissipation region for dissipating the heat. When it is intended to dismount the heat plate 30′ from the circuit board 10, the user operates the handle portion 71 of the attachment 70, so as to make two supporting arms 72 penetrate between the through-hole of the heat plate 30′ and the CPU chip 20, and each supporting arm 72 is located between the contacting region of the heat plate 30′ ad the CPU chip 20 and each through-hole of the heat plate 30′, and the positioning slot 76 is made to be engaged with the locking element 50, so as to position the attachment 70, which is convenient for the subsequent process of dismounting the heat plate 30′. Meanwhile, each buffer element 73 is located between each supporting arm 72 and the circuit board 10. In this manner, the locking element 50 can be dismounted to loose the heat plate 30′. When the first locking element 50 is dismounted, the loosened end of the heat plate 30′ is not forced by the stress effect of the locking element 50, which thus does not become warped. The other end that the locking element 5o is not dismounted is still fixed on the circuit board 10 under the stress effect of the locking element 50, but the end of the heat plate 30′ that is not loosened may press against each supporting arm 72, and thus, each buffer element 73 on each supporting arm 72 may absorb the pressing force of the heat plate 30′.

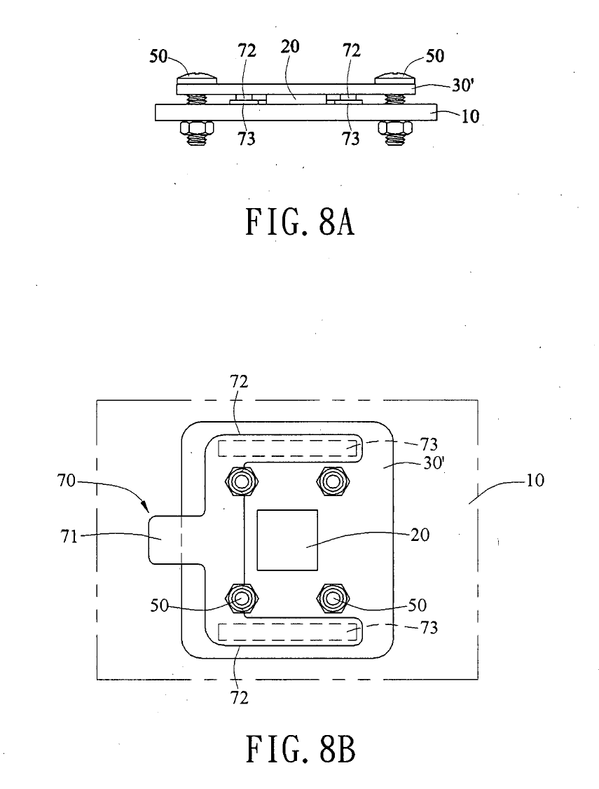

Referring to FIG. 8B, when each supporting arm 72 penetrates the heat plate 30′ and the CPU chip 20, the position is not limited to that mentioned above. When the heat plate 30′ is square-shaped, each supporting arm 72 may be located outside each through-hole of the heat plate 30′. When the heat plate 30′ is dismounted according to the above steps, the buffer element 73 on each supporting arm 72 may also absorb the pressing force of the heat plate 30′.

As that described above, the relative distance between the two supporting arms 72 in the attachment 70 is fixed. If the attachment 70 is applied to the CPU chip 20 with different specifications, it is limited by the relative distance between the two supporting arms 72, such that the applicability of the attachment 70 is limited. Therefore, the present invention further provides another structure of the attachment for dismounting the heat plate.

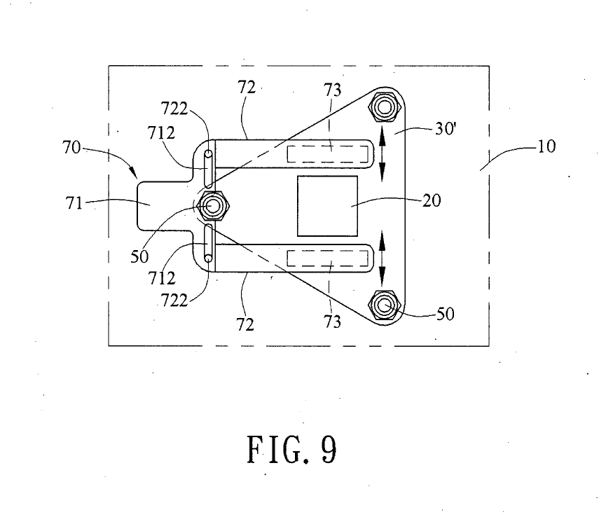

Referring to FIG. 9, the structure of the attachment 70 is approximately the same as that described above, with the difference lying in that, a sliding structure is disposed between each supporting arm 72 and the handle portion 71, such that each supporting arm 72 slides relative to each other and a relative distance is changed. The handle portion 71 has two guide slots 712, and each supporting arm 72 has a sliding block 722, for example, at a position corresponding to each guide slot 712. Each sliding block 722 is extended into and slides within each guide slot 712. In this manner, when the two supporting arms 72 are made to penetrate between the through-hole position of the heat plate 30′ and the CPU chip 20, the user may adjust the relative distance between the two supporting arm 72, depending upon the size of the CPU chip 20, so as to increase the applicability scope. Furthermore, each supporting arm 72 has a guide slot respectively, and the handle portion 71 has two sliding blocks corresponding to the position of each guide slot. Each sliding block is extended into and slides within each guide slot, which also can change the relative distance between the two supporting arms 72. However, it is a corresponding depression and protrusion relationship, which thus is not described in detail any more.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A heat plate construction, applicable for being fixed on a circuit board and contacting with a heat source to perform a heat exchange, comprising:
a heat plate body, having a plurality of fixing points, thereby being fixed on the circuit board and contacting with the heat source, wherein the fixing points are located outside a contacting region between the heat plate body and the heat source; and
at least one buffer element, disposed outside the contacting region between the heat plate body and the heat source, and filled between the heat plate body and the circuit board.

2. The heat plate construction as claimed in claim 1, wherein each fixing point is a through-hole, passing through the heat plate body, for a plurality of locking elements to penetrate there through, and thus fixing the heat plate body on the circuit board.

3. The heat plate construction as claimed in claim 2, wherein each buffer element is located between the contacting region of the heat plate body and the heat source and each through-hole of the heat plate body.

4. The heat plate construction as claimed in claim 2, wherein each buffer element is located outside each through-hole of the heat plate body.

5. The heat plate construction as claimed in claim 1, wherein a thickness of the buffer element is equal to a distance between the heat plate body and the circuit board.

6. The heat plate construction as claimed in claim 1, wherein the buffer element is a resilient element, which has a force for pushing against the heat plate body under a normal state, when the heat plate body is fixed on the circuit board.

7. The heat plate construction as claimed in claim 6, wherein the buffer element is a bakelite.

8. The heat plate construction as claimed in claim 6, wherein an insulating block is further disposed between the buffer element and the circuit board.

9. A heat plate construction, applicable for being fixed on a circuit board and contacting with a heat source to perform a heat exchange, comprising:
a heat plate body, having a plurality of through-holes passing through the heat plate body, for a plurality of locking elements to penetrate there through, thereby being fixed on the circuit board and contacting with the heat source, wherein fixing points are located outside a contacting region between the heat plate body and the heat source; and
at least one buffer element, being a resilient element, filled between the heat plate body and the circuit board, having a force for pushing against the heat plate body under a normal state, wherein the buffer element is located outside the contacting region between the heat plate body and the heat source.

10. The heat plate construction as claimed in claim 9, wherein each buffer element is located between the contacting region of the heat plate body and the heat source and each through-hole of the heat plate body.

11. The heat plate construction as claimed in claim 9, wherein each buffer element is located outside each through-hole of the heat plate body.

12. The heat plate construction as claimed in claim 9, wherein a thickness of the buffer element is equal to a distance between the heat plate body and the circuit board.

13. An attachment for dismounting a heat plate, wherein the heat plate is fixed on a circuit board and contacting with a heat source sandwiched there-between to perform a heat exchange, comprising:
a handle portion, for a user to operate; and
two supporting arms, extending from the handle portion and penetrating between the heat plate and the heat source, each supporting arms extending at least one buffer element, each buffer element is a resilient element disposed on each supporting arm and located between each supporting arm and the circuit board, each buffer element has a force for pushing against each supporting arm under a normal state, and a height of each buffer element together with the supporting arm is equal to a distance between the heat plate and the circuit board.

14. The attachment for dismounting the heat plate as claimed in claim 13, wherein a plurality of through-holes, passing through the heat plate, is disposed at fixing positions of the heat plate, for a plurality of locking elements to penetrate there through, such that the heat plate is fixed on the circuit board and contacts with the heat source, and each through-hole is located outside a contacting region between the heat plate and the heat source.

15. The attachment for dismounting the heat plate as claimed in claim 14, wherein each supporting arm is located between the contacting region of the heat plate and the heat source and each through-hole of the heat plate.

16. The attachment for dismounting the heat plate as claimed in claim 14, wherein each supporting arm is located outside each through-hole of the heat plate.

17. The attachment for dismounting the heat plate as claimed in claim 14, wherein a positioning slot matching with the locking element is further disposed, for engaging with the locking element.

18. The attachment for dismounting the heat plate as claimed in claim 13, wherein a sliding structure is disposed between each supporting arm and the handle portion, such that each supporting arm slides relative to each other and a relative distance is changed.

19. The attachment for dismounting the heat plate as claimed in claim 18, wherein the handle portion has two guide slots, and each supporting arm has a sliding block at a position corresponding to each guide slot that is extended into and slides within each guide slot.

20. The attachment for dismounting the heat plate as claimed in claim 18, wherein each supporting arm has a guide slot respectively, the handle portion has two sliding blocks at positions corresponding to each guide slot that are extended into and slide within each guide slot.
